(19) United States
(12) Patent Application Publication
(10) Pub. No.: US 2009/0090850 A1
(43) Pub. Date: Apr. 9, 2009

(54) Deep Recess Color Filter Array and Process of Forming the Same

(75) Inventors: Saijin Liu, Boise, ID (US); Ulrich C. Boettiger, Boise, ID (US); Salman Akram, Boise, ID (US)

Correspondence Address: DICKSTEIN SHAPIRO LLP, 1825 EYE STREET, NW, WASHINGTON, DC, 20006, US

(73) Assignee: Aptina Imaging Corporation

(21) Appl. No.: 12/333,850

(22) Filed: Dec. 12, 2008

Related U.S. Application Data
(63) Continuation-in-part of application No. 11/513,246, filed on Aug. 31, 2006.

(51) Int. Cl. H01L 31/0232

(52) U.S. Cl. 250/226; 438/29; 257/E21.536

(57) ABSTRACT

Self-aligned color filter array and methods of forming same. Embodiments include an image sensor having a substrate with a fabrication element having a first recess, the first recess having a second recess, a color filter formed in the second recess, and a microlens formed over the color filter.

### CROSS-REFERENCE TO RELATED APPLICATIONS

This application is a continuation-in-part of application Ser. No. 11/513,246, filed Aug. 31, 2006, which is hereby incorporated by reference in its entirety.

### FIELD OF THE INVENTION

Embodiments of the invention relate generally to deep recess color filter arrays and processes of forming the same.

### BACKGROUND OF THE INVENTION

Solid-state image sensors were developed in the late 1960s and early 1970s primarily for television image acquisition, transmission, and display. An imager absorbs incident radiation of a particular wavelength (such as optical photons, x-rays, or the like) and generates an electrical signal corresponding to the absorbed radiation. There are a number of different types of semiconductor-based imagers, including charge coupled devices (CCDs), photodiode arrays, charge injection devices (CIDs), hybrid focal plane arrays, and complementary metal oxide semiconductor (CMOS) imagers. Current applications of solid-state imagers include cameras, scanners, machine vision systems, vehicle navigation systems, star trackers, and motion detector systems, among other uses.

These imagers typically consist of an array of pixels containing photosensors, where each pixel produces a signal corresponding to the intensity of light impinging on its photosensor when an image is focused on the array. These signals may then be processed and stored, for example, for later display, printing, or analysis or are otherwise used to provide information about the image. The photosensors may be phototransistors, photogates, photodiodes, or other light sensitive devices. The magnitude of the signal produced by each pixel is proportional to the amount of light impinging on the photosensor.

To allow the photosensors to capture a color image, the photosensors must be able to separately detect color components of the captured image. For example, in a well known Bayer pattern pixel array red (R) photons, green (G) photons, and blue (B) photons are captured by different pixels of the array. Accordingly, each pixel must be sensitive only to one color or spectral band. For this, a color filter array (CFA) is typically placed in front of the optical path to the photosensors so that each photosensor detects the light of the color of its associated filter. Thus, for a typical Bayer pattern pixel array, each photosensor is covered with either a red, green, or blue filter, according to the Bayer pattern. Other color filter array patterns are also known and used for imaging.

As noted above, color filter arrays are commonly, but not exclusively, arranged in a mosaic sequential pattern of red, green, and blue filters known as the Bayer filter pattern. The Bayer filter pattern is quartet-ordered with successive rows that alternate red and green filters, then green and blue filters. Thus, each red filter is surrounded by four green and four blue filters, while each blue filter is surrounded by four red and four green filters. In contrast, each green filter is surrounded by two red, four green, and two blue filters. U.S. Pat. No. 3,971,065 describes the Bayer pattern color filter array.

Forming a color filter array requires a multi-step fabrication process that can be complex and difficult to implement to obtain good separation of the color filters. Accordingly, there is a need and desire for improved methods of forming color filter arrays. In addition, as image sensor pixel sizes are shrinking, there is a need to reduce their stack height to reduce cross talk between pixels.

### BRIEF DESCRIPTION OF THE DRAWINGS

FIGS. 1A and 1B illustrate partial top-down and cross-sectional views of an image sensor constructed in accordance with a first structural embodiment discussed herein.

FIGS. 2-8 illustrate cross-sectional views of forming the image sensor illustrated in FIGS. 1A and 1B.

FIG. 9 is a partial top-down block diagram view of an imager device including the image sensor illustrated in FIGS. 1A and 1B.

FIG. 10 illustrates a system having the imager device illustrated in FIG. 9.

### DETAILED DESCRIPTION

In the following detailed description, reference is made to various specific embodiments. These embodiments are described with sufficient detail to enable those skilled in the art to practice them, and it is to be understood that other embodiments may be employed, and that structural and electrical changes may be made.

The term “pixel” or “pixel cell” refers to a picture element unit cell containing a photo-conversion device for converting electromagnetic radiation to an electrical signal. For purposes of illustration, a representative three-color Bayer R, G, B pixel array is described herein; however, the disclosed embodiments are not limited to the use of an R, G, B array, and can be used with other color arrays, one example being C, M, Y, K (which represents cyan, magenta, yellow, and grey (black)). Also, for purposes of illustration, a portion of a representative pixel is illustrated in the figures and description herein, and typically fabrication of other pixels in an image sensor will proceed concurrently and in a similar fashion.

Embodiments described herein relate to methods of forming color filters for use in a solid-state image sensor. Although the embodiments are described in relation to use with a CMOS image sensor, they are not so limited and have applicability to any image sensor.

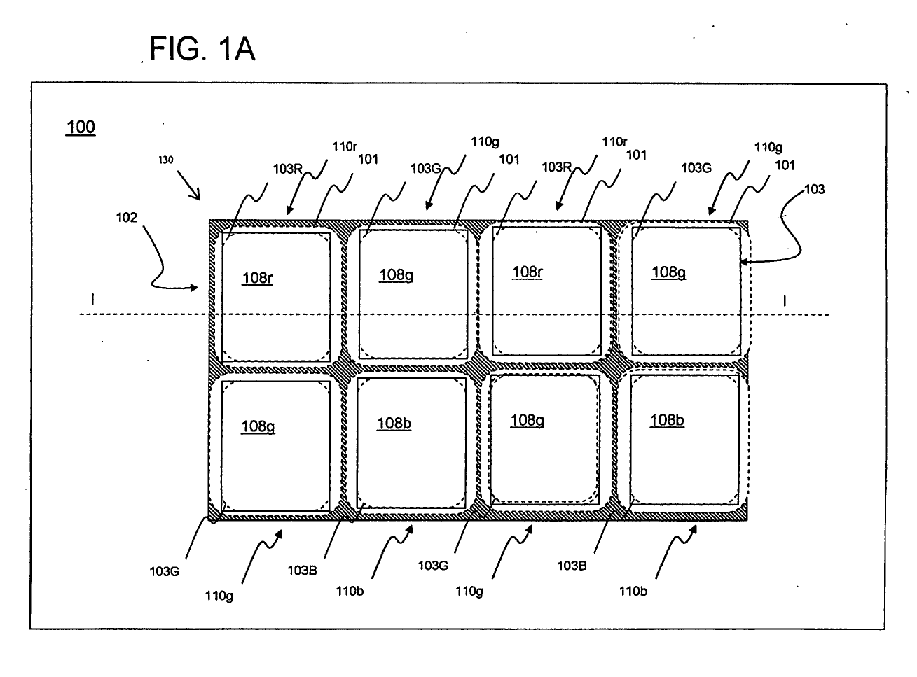

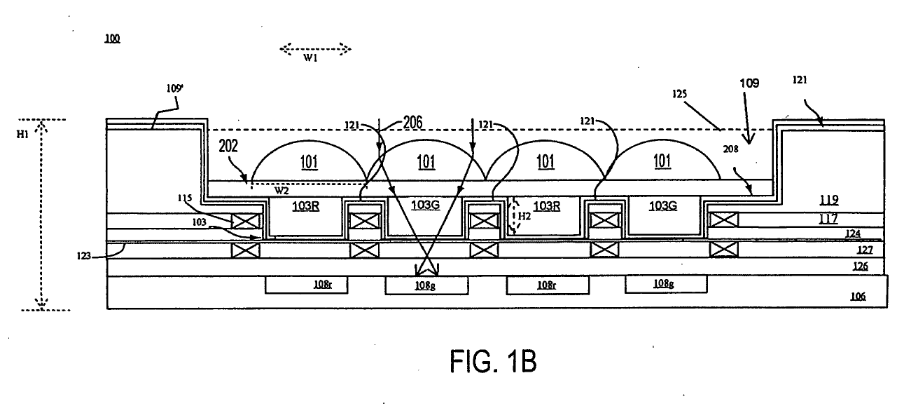

Referring now to the drawings, where like elements are designated by like numerals, FIGS. 1A and 1B illustrate a partial top-down view and side cross-sectional view (taken along line I-I of FIG. 1A), respectively, of a portion of a pixel array 130 of a semiconductor-based image sensor 100, such as a CMOS image sensor, constructed in accordance with a structural embodiment.

As illustrated in FIGS. 1A and 1B, the pixel array 130 includes a plurality of pixel cells including first, second, and third pixel cells 110r, 110g, 110b. The image sensor 100 also includes a microlens array 102 (FIG. 1A) having microlenses 101 formed over a color filter array 103 having respective first, second, and third color filters 103R, 103G, 103B. A microlens 101 is associated with each color filter. The color filter array 103 is illustrated as having a Bayer filter pattern; although, this is not intended to be limiting. Each of the first, second, and third color filters 103R, 103G, 103B allows a particular wavelength of light to pass through to corresponding first, second, and third photosensors 108r, 108g, 108b formed in a semiconductor substrate 106 (FIG. 1B). In the illustrated embodiment, the first, second, and third color filters 103R, 103G, 103B allow corresponding red, green, and blue wavelengths of light to pass through, although this is not intended to be limiting in any way.

As better illustrated in FIG. 1B, the pixel array 130 row (line I-I of FIG. 1A) has alternating first and second photosensors 108r, 108g formed in a semiconductor substrate 106. Other electrical structures of each pixel cell are omitted for clarity. The image sensor 100 has a recess 109 in which the microlenses 101 are formed. Although the microlenses 101 are formed to have a topmost surface 109′ forming a plane 125 below a topmost surface 109′ of the recess 109, it is not intended to be limiting. For example, the microlenses could have a topmost surface 109′ equal to or extending above plane 125. The FIG. 1B microlenses 101 are located within the recess 109, which provides for protection of the microlenses during further processing.

Also illustrated are first, second, third, fourth, fifth, and sixth material elements 126, 127, 123, 124, 117, 119, respectively. The first, second, third, fourth, fifth, and sixth material elements 126, 127, 123, 124, 117, 119 could include layers of boro-phosphosilicate glass (BPSG), dielectric material, thin oxide materials, anti-reflective or metallization materials. In the illustrated embodiment, the first material element 126 is formed of BPSG, the second material element 127 is a first interlayer dielectric layer having metallization elements 115 formed therein, the third material element 123 may be a second interlayer dielectric layer, the fourth material element 124 may be a third interlayer dielectric layer, the fifth material element 117 may be a TEOS (known as tetraethyl orthosilicate, tetraethoxysilan, silic acid tetraethylester, or ethyl silicate) layer, the sixth material element 119 may be a passivation TEOS layer. It should be noted that this is not intended to be limiting; for example, any of the material elements (126, 127, 123, 124, 117, 119) could be thin oxide material elements, antireflective material elements, or any other material element suitable for an intended application. The recess 109 is formed in the upper levels of the material layers, for example, in the upper level of the fifth material layer 117.

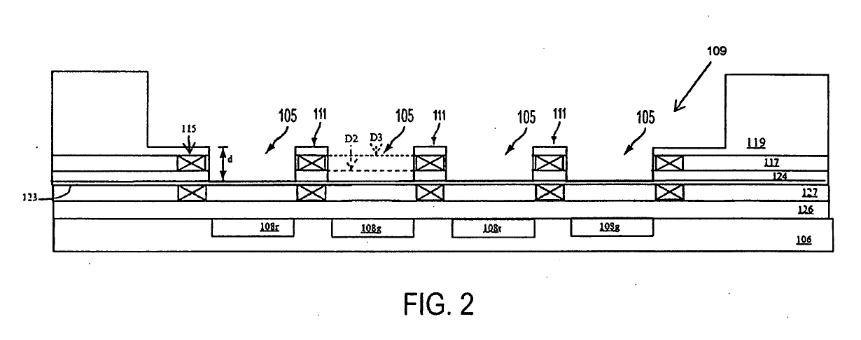

The color filter array 103 is formed within recesses 105 (FIG. 2) formed in the fourth, fifth, and sixth material elements 124, 117, 119. By forming the color filter array directly on top of the third material element 123, the color filter array is formed deep within a topmost surface of the image sensor 100, which may have certain advantages discussed below. The embodiment is not limiting, however; for example, the color filter array may be formed to extend to a topmost surface of any of the first, second, and third material elements 126, 127, 123, respectively. The color filter array may also be formed to extend to a topmost surface of any of the fifth and sixth material elements 124, 117.

The microlenses 101 may optionally be separated from the underlying color filter array 103 by an optional spacer element 202, which may help during fabrication as the microlenses 101 and color filters (e.g., color filters 103R and 103G) can be formed of different cross-sectional sizes. For example, the color filter 103R is embedded in a deep recess 105 (FIG. 2) extending to the third material element 123, and has a smaller cross-sectional horizontal width (W1) as compared to the cross-sectional horizontal width (W2) of the microlens 101 formed over the color filter 103R. The wider cross-sectional horizontal width (W2) of the microlens 101 allows large area coverage to maintain quantum efficiency. The spacer element 202 may also elevate the microlenses 101 by a certain distance such that incoming light 206 can be focused to some extent before it enters the color filters (e.g., color filter 103G) and focused on the respective photosensor 108.

In addition, the color filters (e.g., color filters 103R and 103G) are strictly aligned to the underlying photosensors (e.g., photosensors 108r and 108g) as a result of the color filter array 103 being formed within recesses of the fourth, fifth, and sixth material elements 124, 117, 119. Prior techniques of forming color filters over planar surfaces allow for variability in the manufacturing process; for example, color filter arrays may shift resulting in off-center (relative to underlying photosensors) color filters. The microlenses 101 formed over the color filter array 103 need not be strictly aligned because the spacer element 202 elevates the microlenses 101 such that incoming light 206 can converge to some extent before it enters the color filter arrays (e.g., color filters 103R and 103G), and strike the respective photosensors (e.g., photosensors 108r and 108g).

By forming the color filter array 103 within deep recesses 105 (FIG. 2), the stack height H1 (measured by a cross-sectional distance from a topmost surface of the microlens 101 to a topmost surface of the photosensitive element 108) can be reduced. The color filters illustrated in FIG. 1B have a cross-sectional height H2 of about 0.5 μm; as such, the stack height H1 can be reduced by about 0.5 μm depending on the cross-sectional height of the spacer element 202. The reduction of 0.5 μm may amount to a saving of approximately 25%. For example, an image sensor not having a color filter array that is formed in deep recesses may have a stack height of about 2 μm, whereas the stack height H1 of the image sensor 100 of FIG. 1B is about 1.5 μm, which is a 25% reduction. This is a significant reduction, which significantly reduces pixel cell cross talk. It should be noted that the stack height may be further reduced by not including the optional spacer element.

An optional light blocking material element 121 is also illustrated in FIG. 1B; the light blocking material element 121 is formed over portions of the fourth, fifth, and sixth material elements 124, 117, 119 not having a color filter formed therebetween. The light blocking material element 121 reduces cross-talk between adjacent pixel cells in the array 102 (FIG. 1A). The illustrated light blocking material element 121 is formed over sidewall regions of the deep recesses 105 (FIG. 2) but not on the bottom of recess 105. The light blocking material element 121 is also formed on the topmost surface of stacks 111 (FIG. 2) that define the deep recesses 105 (FIG. 2). The stacks 111 (FIG. 2) form mesas that define the deep recesses 105 (FIG. 2), as discussed in more detail below.

In the illustrated image sensor 100, the optional light blocking material element 121 formed between the first, second, and third color filters 103R, 103G, 103B in the color filter array 103. Off-axis light incident upon the image sensor 100 and intended for capture by the first photosensor 108r are prevented from striking the adjacent photosensor 108g by the light blocking material element 121, thereby reducing the amount of optical cross talk between photosensors. The light blocking material element 121 thereby acts as a light shield between the photosensors.

As shown in FIG. 1B, an optional passivation element 208 is deposited over selected portions of the image sensor 100 to protect the various material components of the image sensor 100.

FIGS. 2-8 illustrate an embodiment for forming the image sensor 100 illustrated in FIGS. 1A and 1B. As illustrated in FIG. 2, the first, second, third, fourth, fifth, and sixth material elements 126, 127, 123, 124, 117, 119 are formed over the substrate 106 in and on which electrical elements of a pixel cell are formed, including the photosensors 108r, 108g. A recess 109 is formed in the sixth material element 119. The recess 109 can be formed by conventional techniques, such as, for example, dry etching, reactive ion etching, or wet etching. Additional deep recesses 105 are formed within recess 109. The deep recesses 105 can also be formed by conventional techniques, such as, for example, dry etching, reactive ion etching, or wet etching. The deep recesses 105 correspond to respective photosensors 108r, 108g formed in the underlying substrate 106. Stacks 111, formed of several material elements (e.g., fourth, fifth, and sixth material elements 124, 117, 119), define the deep recesses 105. Each stack 111 in cross-section has two sidewall regions and a topmost region.

The recesses 105 have a cross-sectional depth in the range of about 0.4 μm to about 1.5 μm, depending on the intended purpose of the image sensor 100, and the metallization process used. Accordingly, the cross-sectional height H2 (FIG. 1B) of the second color filter 103G (FIG. 1B) may also be in the range of about 0.4 μm to about 1.5 μm. It should be noted that the first, second, and third color filters 103R, 103G, 103B (FIG. 1B) may have the same or different dimensions, depending on the intended application of the image sensor 100 (FIGS. 1A and 1B). As discussed above with respect to FIG. 1B, the illustrated image sensor 100 has color filters 103R, (FIG. 1B) 103G having a cross-sectional height H2 (FIG. 1B) of about 0.5 μm.

The illustrated first and second color filters 103R, 103G could each have a cross-sectional width W1 (FIG. 1) in the range from about 1000 nm to about 2000 nm, and are separated from one another by a distance in the range from about 50 nm to about 200 nm (e.g., the stacks 111 (FIG. 2) may have a cross-sectional width in the range of about 50 nm to about 200 nm). It should be noted that the third color filter 103B (FIG. 1A) may have a width in the range from about 1000 nm to about 2000 nm, and that the third color filter 103B (FIG. 1A) may be separated from adjacent color filters in the color filter array 103 in the range from about 50 nm to about 200 nm.

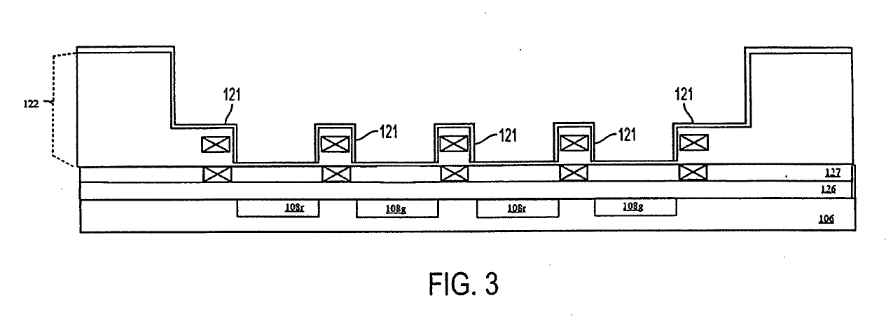

FIG. 3 illustrates the deposition of the light blocking material element 121 over the fourth, fifth, and sixth material elements 124, 117, 119 (FIG. 2), collectively referred to and illustrated as material elements 122 for clarity. Portions of the light blocking material element 121 are then removed by etching areas over the underlying photosensors 108r and 108g. The light blocking material element 121 could be formed of any opaque, reflective, or light absorbing material suitable for the intended application, such as, for example, a metal, metal alloy, metal silicides, aluminum, tungsten, or other opaque material, and is made by any appropriate process. The illustrated light blocking material element 121 has a cross-sectional height of about 30 nm, and is deposited over the sidewall regions and topmost surfaces of the stacks 111 (FIG. 2). In addition, the light blocking material element 121 is also formed on a bottom portion of the recess 109 (FIG. 2), and on the sidewall regions and topmost surfaces of the recess 109, although this is not intended to be limiting. For example, the light blocking material element 121 could be localized to the sidewall regions of the deep recess 105 (FIG. 2) only. The light blocking material element 121 can be deposited by atomic layer deposition (ALD), physical vapor deposition (PVD), chemical vapor deposition, or spin coating deposition, after which it is selectively etched to remove light blocking material element 121 from the bottom of deep recesses 105.

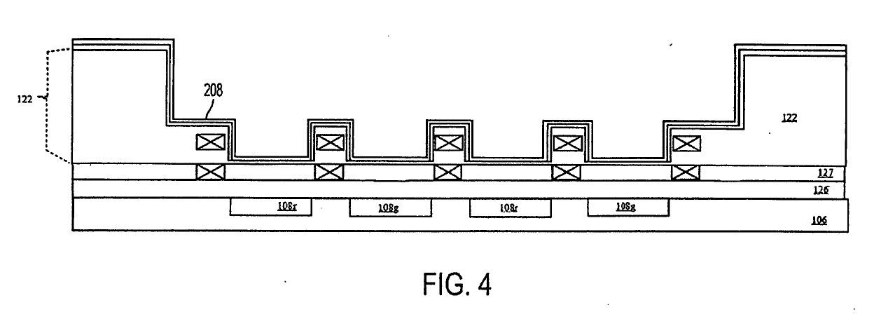

FIG. 4 illustrates the deposition of a passivation element 208 over the exposed surfaces of the FIG. 3 structure. As noted above, the optional passivation element 208 is deposited by any suitable method over selected portions of the image sensor 100 to protect the metal components of the image sensor 100. The passivation element 208 could be formed of a nitride layer or any other suitable material for the intended application.

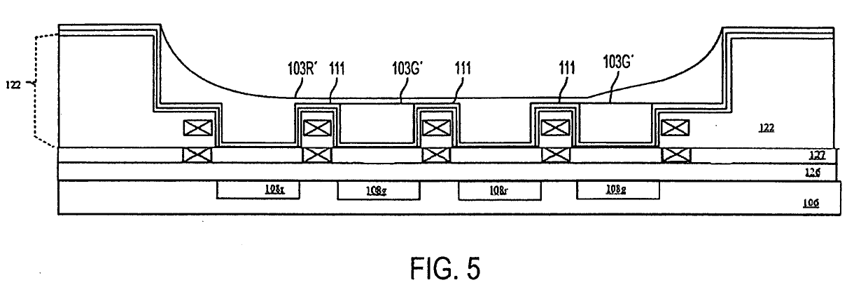

FIG. 5 illustrates the patterned formation of second color filter precursors 103G′. The second color filters 103G′ can be patterned by conventional techniques, such as, for example, using photolithography and a suitable mask (not shown), and selectively depositing materials to form second color filter precursors 103G′. FIG. 5 also illustrates the deposition of a first color filter precursor 103R′. The first color filter precursor 103R′ need not be patterned if it is the last color filter precursor being formed (i.e., formed after the second and third color filter precursors forming second and third color filters 103G and 103B (FIG. 1A)), although it is not intended to be limiting. For example, the first color filter precursor 103R′ may be patterned similar to the second color filter precursors 103G′. The patterned color filter precursors are subsequently baked and hardened to form first, second, and third color filters 103R, 103G, 103B (FIG. 1A).

The color filters of the color filter array 103 formed in recesses 105 (FIG. 2) results in a self-aligned, efficient, and consistent formation that allows for simplified further processing of the image sensor 100 (FIGS. 1A and 1B).

The first and second color filter precursors 103R′ and 103G′ may be formed of a material including, but not limited to, glass, for example, zinc selenide (ZnSe), silicon oxide, silicon nitride, silicon oxynitride, silicon-carbon (SiC) (BLOk), tantalum pentoxide (Ta₂O₅), titanium oxide (TiO₂), polymethylmethacrylate, polycarbonate, polyolefin, cellulose acetate butyrate, polystyrene, polyimide, epoxy resin, photosensitive gelatin, acrylate, methacrylate, urethane acrylate, epoxy acrylate, polyester acrylate, or a positive or negative photoresist such as a 3000 series photoresist material (or any other series of photoresist material) produced by FUJIFILM Electronic Materials (FFEM), Japan, including, but not limited to color resists known in the art as SB-3000L, SG-3000L and SR-3000L for blue, green, and red color filters, respectively. The preceding materials are only illustrative examples.

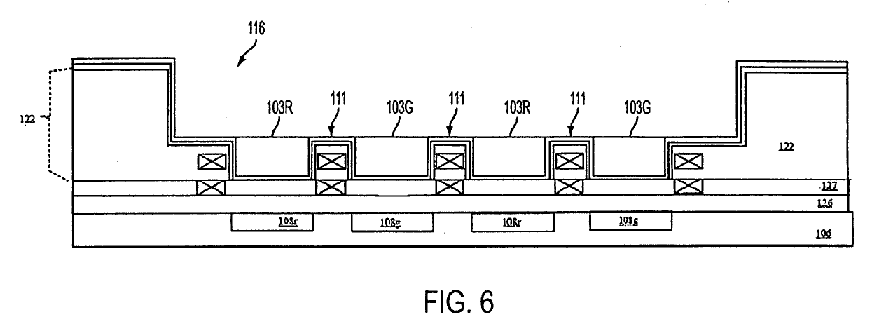

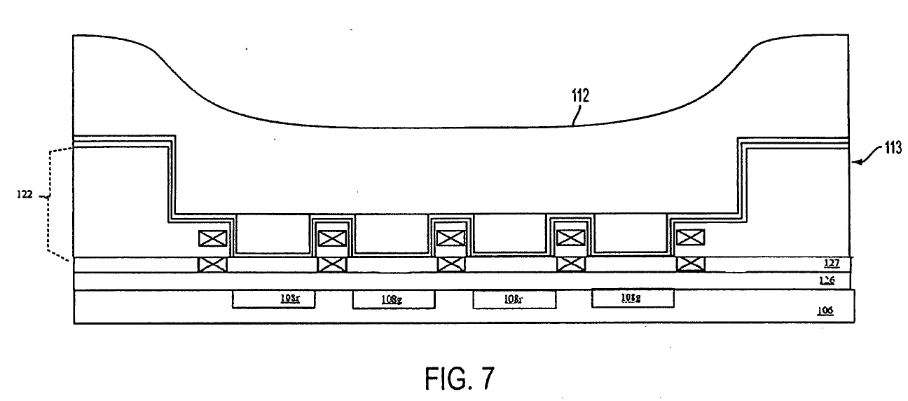

FIG. 6 illustrates the FIG. 5 structure after chemical mechanical polishing (CMP) of the structure to create a recess 116. The polishing step forms a substantially planar surface on which further processing (discussed below with respect to FIG. 7) can take place. As illustrated, the sacrificial portions of the first and second color filter precursors 103R′, 103G′ (FIG. 5) are removed to create the first and second color filters 103R, 103G having a top surface substantially planar to a top surface of the stack 111. Although not illustrated, it should be noted that a third color filter precursor that forms the third color filter 103B (FIG. 1A) is also deposited; the third color filter may be deposited with sacrificial material as well, which is subsequently removed to create a third color filter 103B (FIG. 1A) having a top surface substantially planar to a top surface of the stack 111.

FIG. 7 illustrates the forming of a transparent material 112 within the recess 116 (FIG. 6), and over peripheral portions 113 of the material elements 122. The transparent material could be formed of zinc selenide (ZnSe), silicon oxide, silicon nitride, silicon oxynitride, silicon-carbon (SiC) (BLOk), tantalum pentoxide (Ta₂O₅), titanium oxide (TiO₂), polymethylmethacrylate, polycarbonate, polyolefin, cellulose acetate butyrate, polystyrene, polyimide, epoxy resin, photosensitive gelatin, acrylate, methacrylate, urethane acrylate, epoxy acrylate, polyester acrylate, or a positive or negative photoresist such as a 3000 series photoresist material (or any other series of photoresist material) produced by FUJIFILM Electronic Materials (FFEM), Japan. The preceding materials are only illustrative examples.

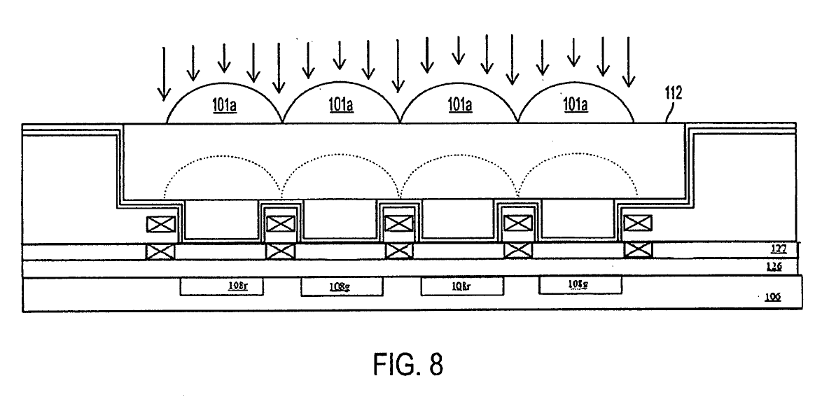

FIG. 8 illustrates the forming of shaping elements 101a over the planarized transparent material 112. The shaping elements 101a could be formed of the same or different material as the transparent material 112. The shape of the shaping elements 101a is transferred into the transparent material 112 to form microlenses 101 (FIGS. 1A and 1B). The transparent material 112 is dry etched to transfer the microlens shapes provided by the shaping elements 101a, and to provide the desired cross-sectional height of the spacer element 202 (FIGS. 1A and 1B) formed by the transparent material 112. Alternatively, the spacer element 202 (FIG. 1B) may be etched to a desired cross-sectional height, and microlenses 101 (FIGS. 1A and 1B) can be formed by patterning and baking methods.

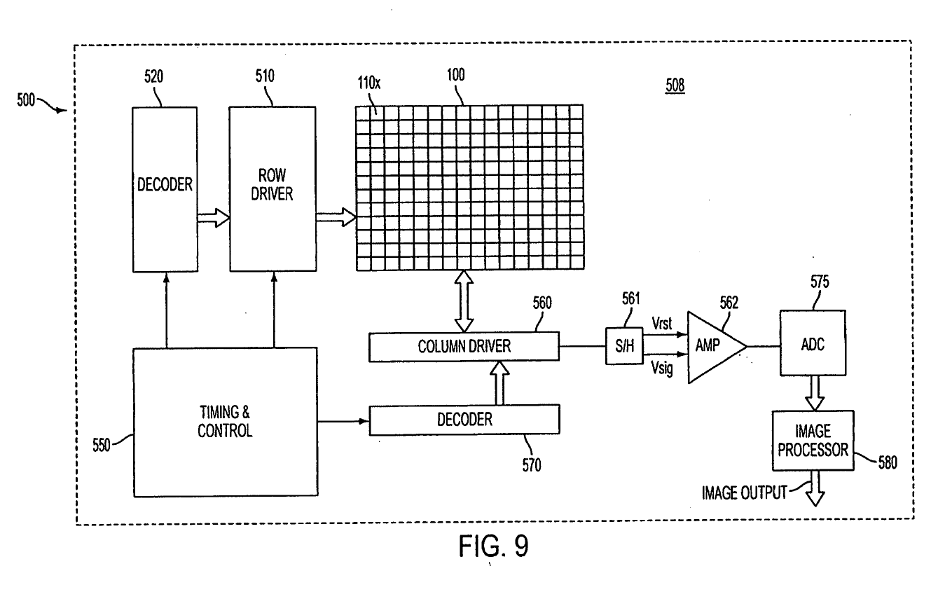

FIG. 9 illustrates an imaging device 508 incorporating the image sensor 100 of FIGS. 1A and 1B. In operation of the FIG. 9 imaging device 508, the pixel cells 110x (representing any of the first, second, and third pixel cells 110r, 110g, 110b of FIG. 1A) of each row in the image sensor 100 are all turned on at the same time by a row select line, and the pixel cells 110x of each column are selectively output by respective column select lines. A plurality of row and column lines are provided for the entire array. The row lines are selectively activated in sequence by the row driver 510 in response to row address decoder 520 and the column select lines are selectively activated in sequence for each row activation by the column driver 560 in response to column address decoder 570. Thus, a row and column address is provided for each of the pixel cells 110x. The imaging device 508 is operated by the control circuit 550, which controls the address decoders 520, 570 for selecting the appropriate row and column lines for pixel readout, and the row and column driver circuitry 510, 560, which apply driving voltage to the drive transistors of the selected row and column lines.

The pixel output signals typically include a pixel reset signal Vrst taken off of a floating diffusion region (via a source follower transistor) when it is reset and a pixel image signal Vsig, which is taken off the floating diffusion region (via the source follower transistor) after charges generated by an image are transferred to it. The Vrst and Vsig signals are read by a sample and hold circuit 561 and are subtracted by a differential amplifier 562, which produces a difference signal (Vrst−Vsig) for each pixel cell 110x, which represents the amount of light impinging on the pixel cell 110x. This signal difference is digitized by an analog-to-digital converter (ADC) 575. The digitized pixel signals are then fed to an image processor 580 to form a digital image output. In addition, as depicted in FIG. 9, the imaging device 508 may be included on a single semiconductor chip (e.g., chip substrate 500).

It should be noted that additional features of the circuitry of the FIG. 9 imaging device 508 are described in U.S. Pat. Nos. 6,140,630; 6,376,868; 6,310,366; 6,326,652; 6,204,524; 6,333,205; and 6,852,591, all of which are assigned to Micron Technology, Inc.

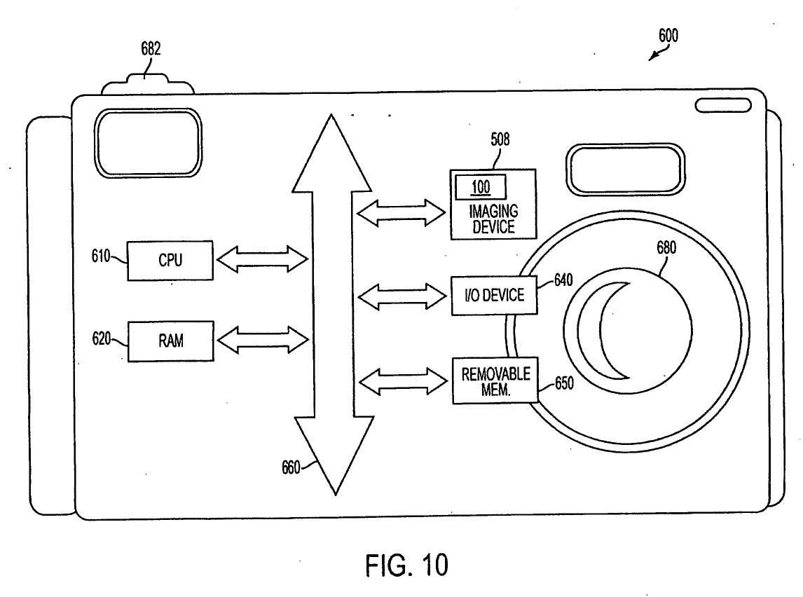

FIG. 10 shows a typical system 600, such as, but not limited to, a camera system. The system 600 is modified to include an imaging device (such as the FIG. 9 imaging device 508). The system 600 is an example of a system having digital circuits that could include image sensor devices. Without being limiting, such a system could include a computer system, camera system, scanner, machine vision, vehicle navigation system, video telephone, surveillance system, automatic focus system, star tracker system, motion detection system, image stabilization system, and other systems employing an image sensor.

System 600, for example, a camera system, includes a lens 680 for focusing an image on image sensor 100, and generally comprises a central processing unit (CPU) 610, such as a microprocessor that controls camera functions and image flow, and communicates with an input/output (I/O) device 640 over a bus 660. CMOS imager device 508 also communicates with the CPU 610 over the bus 660. The system 600 also includes random access memory (RAM) 620, and can include removable memory 650, such as flash memory, which also communicate with the CPU 610 over the bus 660. The imaging device 508 may be combined with the CPU 610, with or without memory storage on a single integrated circuit or on a different chip than the CPU.

It should again be noted that although the embodiments have been described with specific references to CMOS image sensors 100, they have broader applicability and may be used in any imaging apparatus. For example, embodiments may be used in conjunction with charge coupled device (CCD) imagers. The above description and drawings illustrate embodiments which achieve the objects, features, and advantages described. Although certain advantages and embodiments have been described above, those skilled in the art will recognize that substitutions, additions, deletions, modifications and/or other changes may be made.

What is claimed as new and desired to be protected by Letters Patent of the United States is:

1. An image sensor, comprising:
a substrate having a photosensitive element formed therein;
a material element formed over the substrate, the material element having a first recess formed therein, the first recess having a second recess formed therein;
a color filter formed within the second recess; and
a microlens formed over the color filter.

2. The image sensor of claim 1, wherein the microlens has a topmost surface substantially planar to or below a topmost surface defining the first recess.

3. The image sensor of claim 1, further comprising a spacer element formed between the color filter and the microlens.

4. The image sensor of claim 1, wherein a topmost surface of the color filter is substantially planar with a topmost surface of a mesa defining the second recess.

5. The image sensor of claim 1, further comprising an opaque material element formed on at least one sidewall region defining the second recess.

6. The image sensor of claim 4, wherein the opaque material element is formed over a topmost surface of a mesa defining the second recess.

7. The image sensor of claim 1, further comprising a passivation element formed between the color filter and the material element.

8. The image sensor of claim 6, wherein the passivation element is formed over a topmost surface of a mesa defining the second recess.

9. The image sensor of claim 1, wherein the color filter has a cross-sectional height of about 0.5 μm.

10. A method of forming an image sensor, comprising:
forming a photosensitive element within a substrate;
forming a first recess in the substrate, the first recess having a second recess substantially aligned with the photosensitive element;
forming a color filter formed within the second recess;
forming a spacer element formed over the color filter; and
forming a microlens formed over the spacer element, the microlens having a topmost surface below a topmost surface defining the first recess.

11. The method of claim 10, wherein the color filter is formed such that a topmost surface of the color filter is substantially planar with a topmost surface of a mesa defining the second recess.

12. The method of claim 10, further comprising forming an opaque material element on at least one sidewall region defining the second recess.

13. The method of claim 12, wherein the opaque material is formed of a material selected from the group consisting of metal, metal alloy, metal silicides, and aluminum.

14. The method of claim 12, wherein the opaque material element is formed over topmost surfaces of a mesa defining the second recess.

15. The method of claim 10, further comprising forming a passivation element between the color filter and the material element.

16. The method of claim 15, wherein the passivation element is formed over a topmost surface of a mesa defining the second recess.

17. The method of claim 10, wherein the color filter is formed by one of atomic layer deposition, physical vapor deposition, chemical vapor deposition, and spin coating deposition.

18. The method of claim 10, wherein the trench is formed having across-sectional height in the range of about 0.4 μm to about 1.5 μm.

19. The method of claim 10, wherein the color filter has a width in the range from about 1000 nm to about 2000 nm.

20. The method of claim 10, wherein the cross-sectional distance from a top most surface of the microlens to a surface of the photosensitive element is about 1.5 μm.

21. An imaging device, comprising:
a substrate having a photosensitive element array formed therein;
a material element formed over the substrate, the material element having a first recess formed therein, the first recess having a plurality of second recesses corresponding to respective underlying photosensitive elements in the photosensitive element array;
a plurality of color filters formed within the plurality of second recesses;
a spacer element formed over the plurality of color filters; and
a microlens array formed over the spacer element, the microlenses substantially aligned with underlying color filters, and having a topmost surface below a topmost surface defining the first recess.

22. The imaging device of claim 21, wherein a topmost surface of at least one color filter is substantially planar with a topmost surface of a sidewall region defining the second recess.

23. The imaging device of claim 21, further comprising an opaque material element formed on at least one sidewall region defining the second recess.

24. The imaging device of claim 23, wherein the opaque material element is formed over topmost surfaces of stacks defining the second recess.

25. The imaging device of claim 21, further comprising a passivation element formed between each of the color filters and the material element. cm 26. The imaging device of claim 21, wherein the color filter has a cross-sectional height of about 0.5 μm.
